(19) United States
(12) Patent Application Publication
(10) Pub. No.: US 2008/0169493 A1
(43) Pub. Date: Jul. 17, 2008

(54) Semiconductor devices and dynamic random access memories having a retrograde region and methods of forming the same

(76) Inventors: Jin-Woo Lee, Gyeonggi-do (KR); Tae-Young Chung, Gyeonggi-do (KR)

Correspondence Address: MYERS BIGEL SIBLEY & SAJOVEC, PO BOX 37428, RALEIGH, NC, 27627, US

(21) Appl. No.: 11/809,252

(22) Filed: May 31, 2007

(30) Foreign Application Priority Data
Jan. 15, 2007 (KR) 2007-0004308

(51) Int. Cl. H01L 27/108; H01L 21/336; H01L 29/78

(52) U.S. Cl. 257/296; 257/330; 438/270; 257/E21.409; 257/E29.255; 257/E27.084

(57) ABSTRACT

Semiconductor devices include an active region defined in a semiconductor substrate having first type impurity ions. A retrograde region is in the active region and has second type impurity ions. An upper channel region is on the retrograde region in the active region and has the first type impurity ions. Source and drain regions are on the upper channel region in the active region and spaced apart from each other. A gate electrode fills a gate trench formed in the active region. The gate electrode is disposed between the source and drain regions and extends into the retrograde region through the upper channel region. DRAM devices and methods are also provided.

### CROSS-REFERENCE TO RELATED APPLICATION

This application is related to and claims priority under 35 USC § 119 from Korean Patent Application No. 10-2007-0004308, filed on Jan. 15, 2007 in the Korean Intellectual Property Office, the disclosure of which is incorporated herein by reference in its entirety

### BACKGROUND OF THE INVENTION

The present invention relates to semiconductor devices and methods of forming the same, and more particularly, to semiconductor devices having a retrograde region and methods of forming the same.

As semiconductor (integrated circuit) devices become more highly integrated, research is being carried out on effects of an extreme reduction of transistor size. When the planar size of a gate electrode is reduced to reduce the transistor size, problems, such as an increase in off-current and deterioration in refresh characteristics due to a short channel effect, generally occur.

To deal with such a short channel effect, a recess channel transistor having a relatively long effective channel length compared to the planar size has been proposed.

The recess channel transistor includes a gate trench formed by etching a semiconductor substrate, and a gate electrode filling the gate trench. That is, the gate electrode has a structure extending into the semiconductor substrate. When a gate voltage not less than a threshold voltage is applied to the gate electrode, a channel of the recess channel transistor may be formed in the semiconductor substrate corresponding to a lower surface of the gate electrode.

Accordingly, an effective channel length of the recess channel transistor may be increased in proportion to the depth of the gate trench. That is, the effective channel length of the recess channel transistor may be increased by forming a deep gate trench.

However, the increase in depth of the gate trench may exaggerate an increase in threshold voltage due to a body effect. In general, the semiconductor substrate is grounded or a body bias is applied to the semiconductor substrate. The body bias typically changes the threshold voltage of the transistor. For example, the body bias may be a negative voltage when the gate voltage is positive. In this case, the threshold voltage of the transistor may be increased in proportion to the magnitude of the body bias.

Here, the increase in depth of the gate trench may accelerate increase of a rate of the threshold voltage due to the body bias. The increase in threshold voltage may make it difficult to implement a semiconductor device having a low operating voltage.

A semiconductor device having a retrograde region in a channel region is disclosed in U.S. Patent Publication No. 2003/0183856A1, entitled “Semiconductor device having a retrograde dopant profile in a channel region and method for fabricating the same,” to Weiczorek et al.

### SUMMARY OF THE INVENTION

In some embodiments of the present invention, semiconductor devices include an active region defined in a semiconductor substrate having first type impurity ions. A retrograde region is in the active region and has second type impurity ions. An upper channel region is on the retrograde region in the active region and has the first type impurity ions. Source and drain regions are on the upper channel region in the active region and spaced apart from each other. A gate electrode fills a gate trench formed in the active region. The gate electrode is disposed between the source and drain regions and extends into the retrograde region through the upper channel region.

In further embodiments, the first type is a P type and the second type is an N type. The retrograde region may phosphorous and the upper channel region may contain boron.

In other embodiments, the gate trench includes an upper trench and a lower trench. The lower trench is connected to a lower portion of the upper trench and has a larger width than the upper trench and has a bottom at a lower level than a top surface of the retrograde region so that the lower trench extends into the retrograde region. The gate electrode may include an upper and lower gate electrode. The an upper gate electrode may fill the upper trench and the lower gate electrode may fill the lower trench and have a substantially spherical shape. An insulating spacer may be provided between the upper gate electrode and the source and drain regions. A lower channel region may be provided between the lower gate electrode and the retrograde region that has the first type impurity ions. The upper and lower channel regions may define a channel region having the first type impurity ions that extends between and connects the source and drain regions. The source and drain regions may have the second type impurity ions.

In further embodiments, an isolation layer defines the active region. The retrograde region has a top surface disposed at a higher level than the bottom of the isolation layer to provide a side wall region where the isolation layer contacts the retrograde region.

In yet other embodiments, dynamic random access memories (DRAMs) include a semiconductor substrate having first type impurity ions. An active region is defined in the semiconductor substrate. A retrograde region in the active region has second type impurity ions. An upper channel region on the retrograde region in the active region has the first type impurity ions. Source and drain regions on the upper channel region in the active region are spaced apart from each other. A gate electrode fills a gate trench in the active region. The gate electrode is disposed between the source and drain regions and extends into the retrograde region through the upper channel region. A lower channel region in the gate trench is interposed between the gate electrode and the retrograde region. The upper and lower channel regions define a channel region extending between and connecting the source and drain regions. The retrograde region electrically isolates the upper and lower channel regions from the semiconductor substrate to control an increase in threshold voltage due to body bias. An insulating layer is on the upper channel region. A buried contact plug extends through the insulating layer and contacts the source region or the drain region. A storage node on the insulating layer contacts the buried contact plug. The first type may be a P type and the second type may be an N type.

In further embodiments, the DRAM further includes an isolation layer defining the active region. The retrograde region has a top surface disposed at a higher level than the bottom of the isolation layer to provide a side wall region where the isolation layer is in contact with the retrograde region. The insulating layer may be a lower and an upper insulating layer, the storage node being on the upper insulating layer, and the DRAM may further include a bit line on the lower insulating layer and a bit plug extending through the lower insulating layer and connecting the bit line with the other of the source and drain regions.

In other embodiments, the gate electrode includes upper and lower gate electrodes. The upper gate electrode is between the source and drain regions. The lower gate electrode is connected to a lower portion of the upper gate electrode and has a larger width than the upper gate electrode. The lower gate electrode extends to a lower level than a top surface of the retrograde region so that the lower gate electrode extends into the region. The lower gate electrode has a spherical shape. The lower channel region may be interposed between the lower gate electrode and the retrograde region and the upper channel region and the lower channel region may have the P type impurity ions.

In yet further embodiments, methods of forming a semiconductor device include providing a semiconductor substrate having first type impurity ions and an active region. Second type impurity ions are implanted into the active region to form a retrograde region. A gate trench is formed in the active region that has a bottom at a lower level than an top surface of the retrograde region to extend the gate trench into the retrograde region. A gate electrode is formed filling the gate trench and extending into the retrograde region.

In other embodiments, providing a semiconductor substrate is preceded by forming an isolation layer in the semiconductor substrate to define the active region. The isolation layer has a lower end disposed at a lower level than the top surface of the retrograde region to provide a side wall region where the isolation layer is in contact with the retrograde region. Forming the gate trench may include partially etching the active region to form an upper trench and forming a lower trench below the upper trench. The lower trench may have a larger width than the upper trench and have a bottom disposed at a lower level than the top surface of the retrograde region. Forming the lower trench may be preceded by forming an insulating spacer on a sidewall of the upper trench.

In further embodiments, the method further includes implanting the first type impurity ions between the gate electrode and the retrograde region to form a lower channel region. The first type may be a P type and the second type may be an N type. The method may further include implanting the first type impurity ions into the active region on the retrograde region to form an upper channel region on the retrograde region and implanting the second type impurity ions into the active region on the upper channel region to form source and drain regions.

In yet other embodiments, the method further includes implanting the first type impurity ions between the gate electrode and the retrograde region to form a lower channel region. The lower channel region and upper channel region define a channel region having the first type impurity ions extending between and connecting the source and drain regions having the second type impurity ions.

### BRIEF DESCRIPTION OF THE DRAWINGS

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a cross-sectional view of a semiconductor device having a retrograde region according to some embodiments of the present invention.

FIGS. 2 to 9 are cross-sectional views illustrating a method of fabricating (forming) a semiconductor device having a retrograde region according to some embodiments of the present invention.

FIGS. 10 and 11 are cross-sectional views illustrating a method of fabricating (forming) a semiconductor device having a retrograde region according to other embodiments of the present invention.

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and this specification and will not be interpreted in an idealized or overly formal sense unless expressly so defined herein.

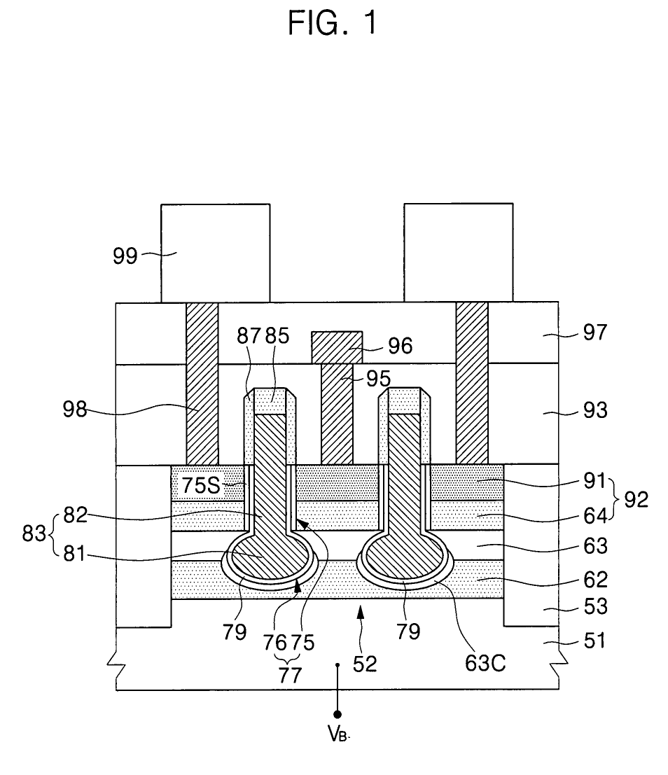

FIG. 1 is a cross-sectional view of a portion of a dynamic random access memory (DRAM) having a retrograde region according to some embodiments of the present invention. Referring to FIG. 1, an isolation layer 53 defining an active region 52 may be provided in a predetermined region of a semiconductor (integrated circuit) substrate 51.

The semiconductor substrate 51 may be a silicon wafer having first type impurity ions. The isolation layer 53 may be disposed to surround sidewalls of the active region 52. The isolation layer 53 may be an insulating layer, such as a silicon oxide layer, a silicon nitride layer and/or a silicon oxynitride layer. The first type may be a P type or an N type.

The active region 52 may have a retrograde region 62, an upper channel region 63, and source and drain regions 92. A top surface of the retrograde region 62 may be higher than a bottom surface of the isolation layer 53. In this case, the retrograde region 62 may be in contact with sidewalls of the isolation layer 53. The retrograde region 62 may have second type impurity ions. The second type impurity ions have a different conductivity type from the first type impurity ions. For example, the second type may be an N type when the first type is a P type, and may be a P type when the first type is an N type.

Hereinafter, for descriptive purposes, it is assumed that the first type is a P type and the second type is an N type. In this case, the second type impurity ions may be N type impurity ions, and the N type impurity ions may be, for example, phosphorus and/or arsenic. The retrograde region 62 may contain the phosphorus in some embodiments of the present invention. Also, the first type impurity ions may be P type impurity ions, and the P type impurity ions may be, for example, boron (B) and/or boron difluoride (BF₂).

The upper channel region 63 may be disposed on the retrograde region 62. The upper channel region 63 may be in contact with a top surface of the retrograde region 62. The upper channel region 63 may have the first type impurity ions. That is, the upper channel region 63 may contain B and/or BF₂.

The source and drain regions 92 may be spaced apart from each other on the upper channel region 63. The source and drain regions 92 may be in contact with a top surface of the upper channel region 63. The source and drain regions 92 may have the second type impurity ions. The source and drain regions 92 may include a low-concentration impurity region 64 and a high-concentration impurity region 91 which are sequentially stacked.

A gate electrode 83 may be disposed to fill a gate trench 77 formed in the active region 52. The gate electrode 83 may be a conductive layer such as a polysilicon layer, a metal layer, a metal silicide layer, or a combination thereof.

The gate trench 77 may have an upper trench 75 and a lower trench 76. The upper trench 75 may be disposed between the source and drain regions 92. The lower trench 76 may be connected to the lower portion of the upper trench 75. The lower trench 76 may have a larger width than the upper trench 75. The lower trench 76 may have a bottom at a lower level than a top surface of the retrograde region 62. That is, the lower trench 76 may penetrate the upper channel region 63 to extend into the retrograde region 62. The lower trench 76 may have a spherical shape.

The gate electrode 83 may include an upper gate electrode 82 filling the upper trench 75 and a lower gate electrode 81 filling the lower trench 76. The lower gate electrode 81 may have a spherical shape.

A lower channel region 63C having the first type impurity ions may be interposed between the lower gate electrode 81 and the retrograde region 62. That is, the lower channel region 63C may contain B or BF₂. The lower channel region 63C may be disposed within the active region 52.

The gate electrode 83 may be disposed to cross the upper channel region 63. In this case, the upper channel region 63 may be separated at both sides of the gate electrode 83. One end of the lower channel region 63C may be in contact with one region of the separated upper channel regions 63. The other end of the lower channel region 63C may be in contact with the other region of the separated upper channel regions 63. Consequently, the separated upper channel regions 63 may be electrically connected to each other by the lower channel region 63C.

An insulating spacer 75S may be interposed between the upper gate electrode 82 and the source and drain regions 92. The insulating spacer 75S may be a silicon nitride layer, a silicon oxide layer and/or a silicon oxynitride layer. In some embodiments, the insulating spacer 75S may be omitted.

A gate dielectric layer 79 may be interposed between the gate electrode 83 and the active region 52. The gate dielectric layer 79 may be an insulating layer such as a silicon nitride layer, a silicon oxide layer, a silicon oxynitride layer and/or a high-k dielectric layer. Specifically, the gate dielectric layer 79 may be interposed between the insulating spacer 75S and the upper gate electrode 82, may be interposed between the upper channel region 63 and the lower gate electrode 81, and may be interposed between the lower channel region 63C and the lower gate electrode 81. The gate electrode 83 may be insulated from the active region 52 by the gate dielectric layer 79.

An insulating pattern 85 may be disposed on the upper gate electrode 82. The insulating pattern 85 may be an insulating layer such as a silicon nitride layer, a silicon oxide layer and/or a silicon oxynitride layer.

The upper gate electrode 82 may protrude from top surfaces of the source and drain regions 92. In this case, gate spacers 87 may be disposed on sidewalls of the insulating pattern 85 and the upper gate electrode 82. The gate spacers 87 may be an insulating layer such as a silicon nitride layer, a silicon oxide layer and/or a silicon oxynitride layer.

In some embodiments, the insulating pattern 85 and the upper gate electrode 82 may be disposed at a lower level than the top surfaces of the source and drain regions 92. In this case, the insulating pattern 85 and the upper gate electrode 82 may be disposed within the upper trench 75.

The entire surface of the semiconductor substrate 51 having the gate electrode 83 may be covered with a lower insulating layer 93. The lower insulating layer 93 may be a silicon nitride layer, a silicon oxide layer, a silicon oxynitride layer and/or a low-k dielectric layer. The lower insulating layer 93 may have a planarized top surface.

A bit line 96 may be disposed on the lower insulating layer 93. The bit line 96 may be electrically connected to a selected one of the source and drain regions 92 by a bit plug 95 through the lower insulating layer 93. That is, one end of the bit plug 95 may be in contact with the bit line 96 and the other end of the bit plug 95 may be in contact with the selected one of the source and drain regions 92. The bit plug 95 and the bit line 96 may be a conductive layer, such as a polysilicon layer, a metal layer and/or a metal silicide layer.

The bit line 96 and the lower insulating layer 93 may be covered with an upper insulating layer 97. The upper insulating layer 97 may be a silicon nitride layer, a silicon oxide layer, a silicon oxynitride layer and/or a low-k dielectric layer. The upper insulating layer 97 may have a planarized top surface.

A storage node 99 may be disposed on the upper insulating layer 97. The storage node 99 may be a lower electrode of a capacitor. The storage node 99 may be a conductive layer such as a polysilicon layer, a metal layer and/or a metal silicide layer.

The storage node 99 may be electrically connected to the other of the source and drain regions 92 by a buried contact plug 98, which penetrates the upper insulating layer 97 and the lower insulating layer 93. That is, one end of the buried contact plug 98 may be in contact with the storage node 99, and the other end of the buried contact plug 98 may be in contact with the other of the source and drain regions 92. The buried contact plug 98 may be a conductive layer, such as a polysilicon layer, a metal layer and/or a metal silicide layer.

When a gate voltage not less than a threshold voltage is applied to the gate electrode 83, a channel may be formed in the upper channel region 63 and the lower channel region 63C, which correspond to a lower surface of the gate electrode 83. That is, the gate trench 77 may be used to increase an effective channel length.

A body bias V_{B} may be applied to the semiconductor substrate 51. In this case, the upper channel region 63 and the lower channel region 63C may be electrically isolated from the semiconductor substrate 51 by the retrograde region 62. Therefore, in some embodiments, it is possible to effectively control the increase in threshold voltage due to the body bias V_{B}.

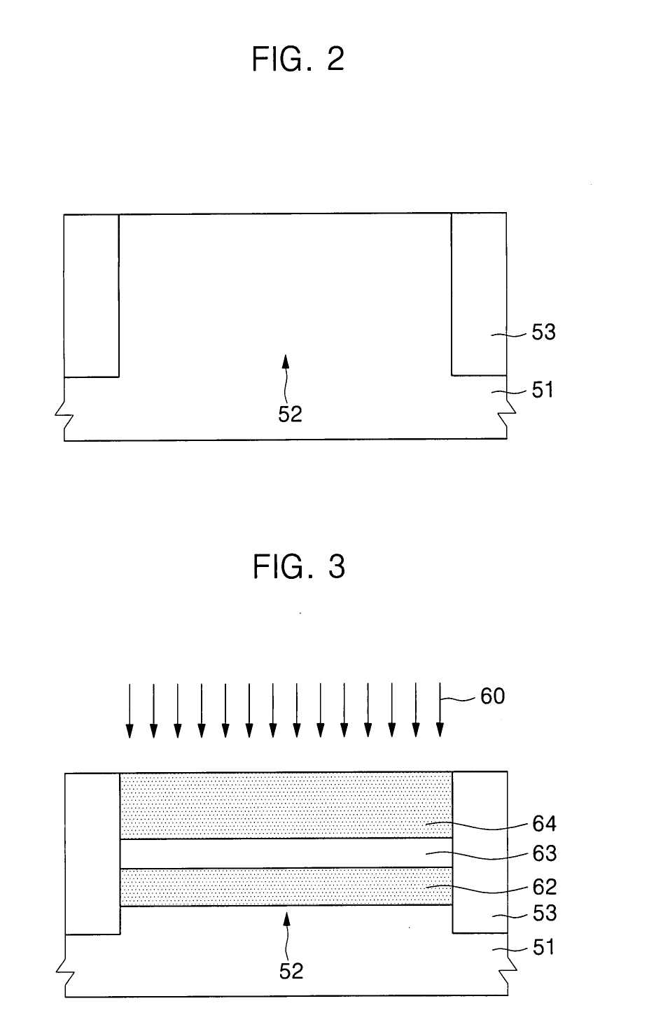

FIGS. 2 to 9 are cross-sectional views illustrating a method of fabricating a semiconductor device having a retrograde region according to some embodiments of the present invention. Referring to FIG. 2, an isolation layer 53 defining an active region 52 may be formed in a predetermined region of a semiconductor substrate 51.

The semiconductor substrate 51 may be formed of a silicon wafer having first type impurity ions. The isolation layer 53 may be formed by a trench isolation technique. The isolation layer 53 may be formed to surround sidewalls of the active region 52. The isolation layer 53 may be formed of an insulating layer, such as a silicon oxide layer, a silicon nitride layer and/or a silicon oxynitride layer. The first type may be a P or N type.

Hereinafter, for descriptive purposes, it is assumed that the first type is a P type. The first type impurity ions may be P type impurity ions, and the P type impurity ions may be, for example, B and/or BF₂.

Referring to FIG. 3, second type impurity ions may be implanted into the active region 52 by a first ion implantation process 60 to form a retrograde region 62. The retrograde region 62 may be in contact with sidewalls of the isolation layer 53. A top surface of the retrograde region 62 may be disposed at a higher level than the bottom of the isolation layer 53.

The second type impurity ions have a different conductivity type from the first type impurity ions. The second type may be an N type when the first type is a P type, and may be a P type when the first type is an N type.

Hereinafter, for descriptive purposes it is assumed that the first type is a P type and the second type is an N type. In this case, the second type impurity ions may be N type impurity ions, and the N type impurity ions may be, for example, phosphorus and/or arsenic. The retrograde region 62 may contain the phosphorous in accordance with some embodiments of the present invention.

The first type impurity ions may be implanted into the active region 52 on the retrograde region 62 to form an upper channel region 63. In this case, the upper channel region 63 may contain B and/or BF₂. The upper channel region 63 may be in contact with a top surface of the retrograde region 62.

The second type impurity ions may be implanted into the active region 52 on the upper channel region 63 to form a low-concentration impurity region 64. The low-concentration impurity region 64 may be in contact with a top surface of the upper channel region 63.

As shown in FIG. 3, the retrograde region 62, the upper channel region 63, and the low-concentration impurity region 64 are stacked within the active region 52. Also, the upper channel region 63 may be electrically isolated from the semiconductor substrate 51 by the retrograde region 62.

Formation of the low-concentration impurity region 64 may be omitted in some embodiments of the present invention. In this case, the low-concentration impurity region 64 may be formed by a subsequent process. In still other embodiments, both the upper channel region 63 and the low-concentration impurity region 64 at this stage may be omitted. In this case, the upper channel region 63 and the low-concentration impurity region 64 may be formed by a subsequent process.

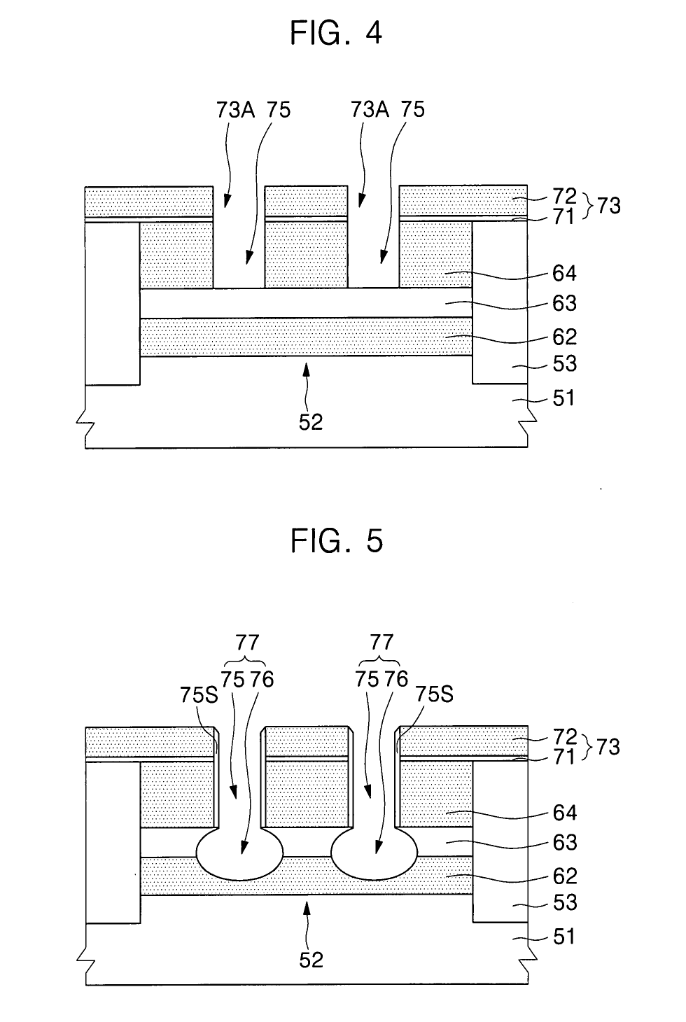

Referring to FIG. 4, a hard mask pattern 73 having an opening 73A which partially exposes the active region 52 may be formed on the semiconductor substrate 51. The hard mask pattern 73 may be formed of a buffer layer 71 and a mask layer 72, which are sequentially stacked.

The buffer layer 71 may be a silicon oxide layer formed by a chemical vapor deposition (CVD) method and/or a thermal oxidation method. The mask layer 72 may be a nitride layer, such as a silicon nitride layer.

The exposed active region 52 may be etched using the hard mask pattern 73 as an etch mask to form an upper trench 75. The upper trench 75 may be formed across the active region 52. Etching the exposed active region 52 may be performed by an anisotropic etching process until the upper channel region 63 is exposed. In this case, the low-concentration impurity region 64 may be separated at both sides of the upper trench 75. That is, a pair of the low-concentration impurity regions 64 spaced apart from each other may remain at both sides of the upper trench 75.

Referring to FIG. 5, an insulating spacer 75S may be formed on sidewalls within the upper trench 75. The insulating spacer 75S may be formed of a material layer having an etch selectivity with respect to the active region 52. The insulating spacer 75S may be formed of a silicon nitride layer, a silicon oxide layer and/or a silicon oxynitride layer.

The exposed upper channel region 63 and the retrograde region 62 may be etched using the insulating spacer 75S and the hard mask pattern 73 as an etch mask to form a lower trench 76. Etching the exposed upper channel region 63 and the retrograde region 62 may be performed by an isotropic etching process and/or an anisotropic etching process.

The lower trench 76 may be connected to a lower portion of the upper trench 75. The lower trench 76 may have a larger width than the upper trench 75. The lower trench 76 may have a bottom at a lower level than a top surface of the retrograde region 62. That is, the lower trench 76 may penetrate the upper channel region 63 to extend into the retrograde region 62. The lower trench 76 may have a spherical shape.

The upper trench 75 and the lower trench 76 may constitute a gate trench 77. As a result, each of the low-concentration impurity region 64 and the upper channel region 63 may be disposed at both sides of the gate trench 77. The bottom of the gate trench 77 may extend into the retrograde region 62. That is, the retrograde region 62, the upper channel regions 63, and the insulating spacer 75S may be exposed within the gate trench 77.

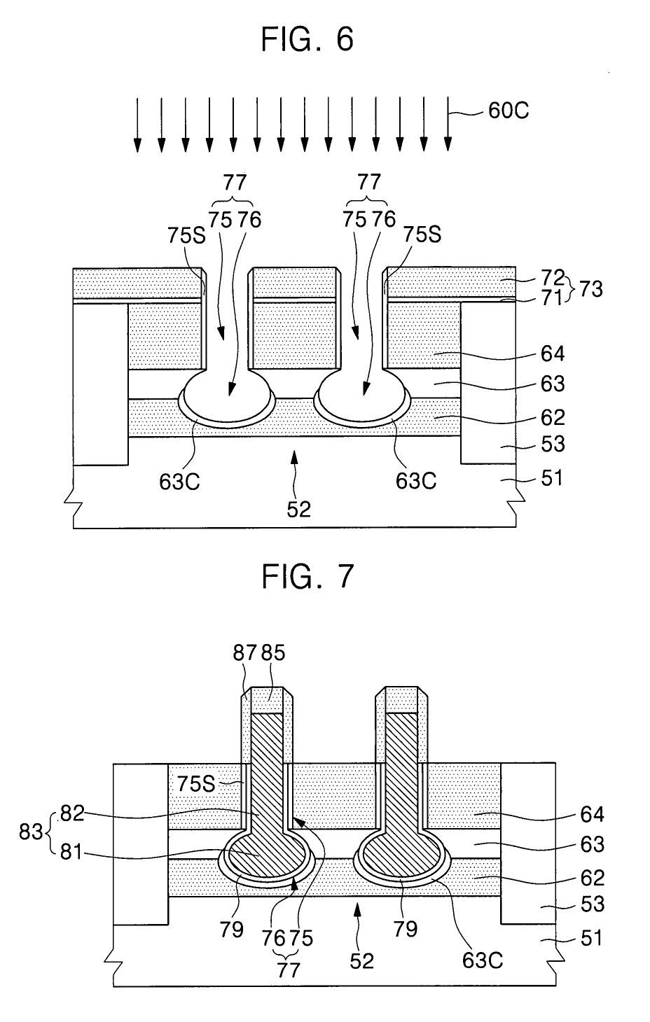

Referring to FIG. 6, the first type impurity ions may be implanted into the exposed retrograde region 62 by a second ion implantation process 60C to form a lower channel region 63C. In this case, the lower channel region 63C may contain B and/or BF₂. The lower channel region 63C may be formed along the bottom surface of the gate trench 77. The retrograde region 62 may remain below the lower channel region 63C extending between the lower channel region 63C and the substrate 51.

One end of the lower channel region 63C may be in contact with one of the separated upper channel regions 63. The other end of the lower channel region 63C may be in contact with the other of the separated upper channel regions 63. Consequently, the separated upper channel regions 63 may be electrically connected to each other by the lower channel region 63C.

Referring to FIG. 7, a gate dielectric layer 79 may be formed in the gate trench 77. The gate dielectric layer 79 may be formed of an insulating layer, such as a silicon nitride layer, a silicon oxide layer, a silicon oxynitride layer and/or a high-k dielectric layer. The gate dielectric layer 79 may have a substantially uniform thickness along an inner wall of the gate trench 77. In this case, the gate dielectric layer 79 may be formed to cover the insulating spacer 75S, the exposed upper channel regions 63 and the lower channel region 63C.

A gate electrode 83 may be formed in the gate trench 77. The gate electrode 83 may be formed of a conductive layer, such as a polysilicon layer, a metal layer and/or a metal silicide layer. The gate electrode 83 may include an upper gate electrode 82 filling the upper trench 75 and a lower gate electrode 81 filling the lower trench 76. The lower gate electrode 81 may have a larger width than the upper gate electrode 82. The lower gate electrode 81 may have a spherical shape.

An insulating pattern 85 may be formed on the upper gate electrode 82. The insulating pattern 85 may be formed of an insulating layer, such as a silicon nitride layer, a silicon oxide layer and/or a silicon oxynitride layer.

The hard mask pattern 73 may be removed to expose the low-concentration impurity region 64. The upper gate electrode 82 may protrude from the top surface of the low-concentration impurity region 64. Gate spacers 87 may be formed on sidewalls of the insulating pattern 85 and the upper gate electrode 82. The gate spacers 87 may be formed of an insulating layer, such as a silicon nitride layer, a silicon oxide layer and/or a silicon oxynitride layer.

In some embodiments, the insulating pattern 85 may be etched while the hard mask pattern 73 is being removed so that the insulating pattern 85 can be fully of partially removed. In some embodiments, the hard mask pattern 73 may be removed before the gate electrode 83 is formed. The upper gate electrode 82 and the insulating pattern 85 may be formed within the upper trench 75. That is, the upper gate electrode 82 may be formed at a lower level than the top surfaces of the low-concentration impurity regions 64. Hereinafter, for descriptive purposes, it is assumed that the upper gate electrode 82 protrudes from the top surfaces of the low-concentration impurity regions 64.

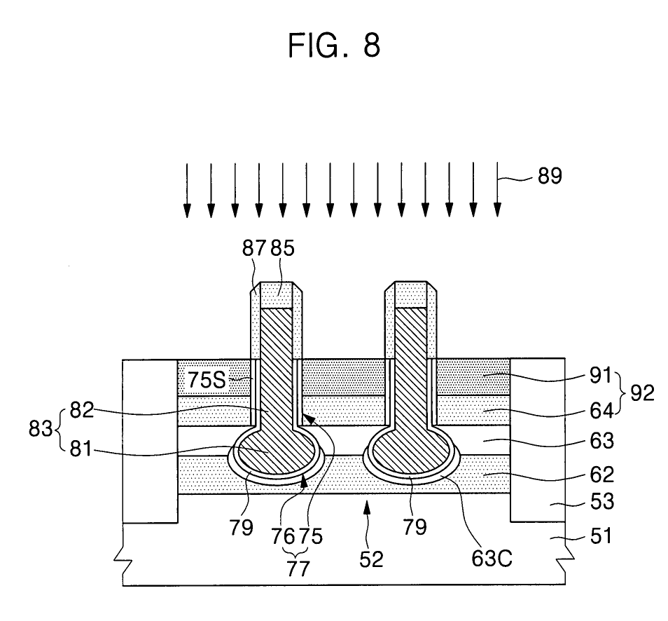

Referring to FIG. 8, the second type impurity ions may be implanted into the exposed low-concentration impurity regions 64 by a third ion implantation process 89 using the gate electrode 83, the insulating pattern 85 and the gate spacers 87 as an ion implantation mask to form high-concentration impurity regions 91. As a result, the low-concentration impurity regions 64 may remain below the high-concentration impurity regions 91.

The low-concentration impurity regions 64 and the high-concentration impurity regions 91 may constitute source and drain regions 92. That is, the source and drain regions 92 may be spaced apart from each other at both sides of the gate electrode 83. The source and drain regions 92 may be in contact with the upper channel regions 63.

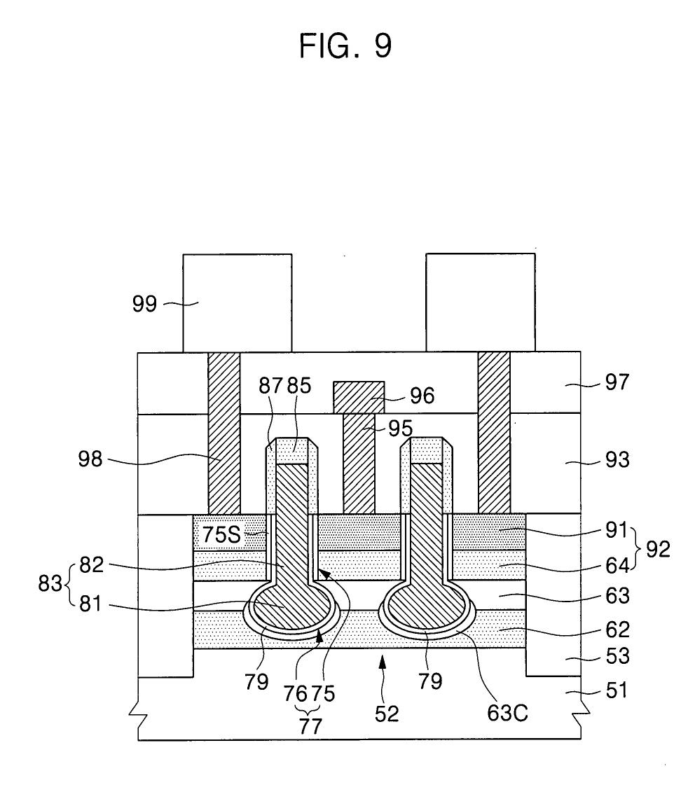

Referring to FIG. 9, a lower insulating layer 93 may be formed to cover the entire surface of the semiconductor substrate 51. The lower insulating layer 93 may be formed of a silicon nitride layer, a silicon oxide layer, a silicon oxynitride layer and/or a low-k dielectric layer. The lower insulating layer 93 may cover the gate electrode 83. The lower insulating layer 93 may be planarized to form a planarized top surface.

A bit plug 95 may be formed through the lower insulating layer 93. A bit line 96, which is in contact with the bit plug 95, may be formed on the lower insulating layer 93. The bit plug 95 may be in contact with a selected one of the source and drain regions 92. That is, the bit line 96 may be electrically connected to the selected one of the source and drain regions 92 via the bit plug 95. The bit plug 95 and the bit line 96 may be formed of a conductive layer, such as a polysilicon layer, a metal layer and/or a metal silicide layer.

An upper insulating layer 97 may be formed to cover the lower insulating layer 93. The upper insulating layer 97 may be formed of a silicon nitride layer, a silicon oxide layer, a silicon oxynitride layer and/or a low-k dielectric layer. The upper insulating layer 97 may cover the bit line 96. The upper insulating layer 97 may be planarized to form a planarized top surface.

A buried contact plug 98 may be formed which penetrates the upper insulating layer 97 and the lower insulating layer 93 to contact the other of the source and drain regions 92. The buried contact plug 98 may be formed of a conductive layer, such as a polysilicon layer, a metal layer and/or a metal silicide layer.

A storage node 99, which is in contact with the buried contact plug 98, may be formed on the upper insulating layer 97. The storage node 99 may be a lower electrode of a capacitor. The storage node 99 may be formed of a conductive layer, such a polysilicon layer, a metal layer and/or a metal silicide layer. The storage node 99 may be electrically connected to the other of the source and drain regions 92 via the buried contact plug 98.

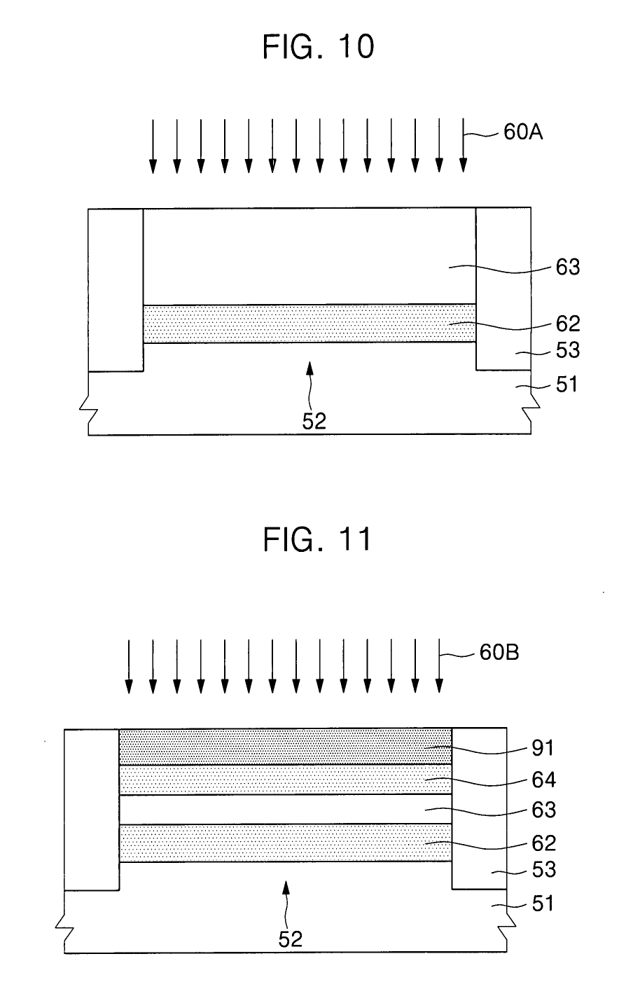

FIG. 10 is a cross-sectional view illustrating a method of fabricating a semiconductor device having a retrograde region according to further embodiments of the present invention. Referring to FIG. 10, the method of fabricating the semiconductor device may include forming the active region 52 and the isolation layer 53 as described above with reference to FIG. 2. Hereinafter, only differences from the previously discussed embodiments will be further described.

The second impurity ions may be implanted into the active region 52 by a fourth ion implantation process 60A to form a retrograde region 62. The retrograde region 62 may be in contact with sidewalls of the isolation layer 53. The retrograde region 62 may have its top surface at a higher level than the bottom of the isolation layer 53. The second type impurity ions may be N type impurity ions, and the N type impurity ions may be, for example, phosphorus and/or arsenic. The retrograde region 62 may contain the phosphorous.

The first type impurity ions may be implanted into the active region 52 on the retrograde region 62 to form an upper channel region 63. The upper channel region 63 may contain B and/or BF₂. The upper channel region 63 may be in contact with a top surface of the retrograde region 62.

As a result, the retrograde region 62 and the upper channel region 63 may be stacked within the active region 52. Also, the upper channel region 63 may be electrically isolated from the semiconductor substrate 51 by the retrograde region 62. In some embodiments, the formation of the upper channel region 63 may be omitted at this stage and the upper channel region 63 may be formed by a subsequent process.

FIG. 11 is a cross-sectional view illustrating a method of fabricating a semiconductor device having a retrograde region according to other embodiments of the present invention. Referring to FIG. 11, the method of fabricating the semiconductor device may include forming the active region 52 and the isolation layer 53 as described above with reference to FIG. 2. Hereinafter, only differences from the previously discussed embodiments will be further described.

The second impurity ions may be implanted into the active region 52 by a fifth ion implantation process 60B to form a retrograde region 62. The retrograde region 62 may be in contact with sidewalls of the isolation layer 53. The retrograde region 62 may have its top surface at a higher level than the bottom of the isolation layer 53.

The second type impurity ions may be N type impurity ions, and the N type impurity ions may be phosphorus and/or arsenic. The retrograde region 62 may contain phosphorus.

The first type impurity ions may be implanted into the active region 52 on the retrograde region 62 to form an upper channel region 63. In this case, the upper channel region 63 may contain B and/or BF₂. The upper channel region 63 may be in contact with a top surface of the retrograde region 62.

The second type impurity ions may be implanted into the active region 52 on the upper channel region 63 to form a low-concentration impurity region 64. The low-concentration impurity region 64 may be in contact with a top surface of the upper channel region 63.

The second type impurity ions may be implanted into the low-concentration impurity region 64 to form a high-concentration impurity region 91. The high-concentration impurity region 91 may be formed along the surface of the low-concentration impurity region 64. As a result, the low-concentration impurity region 64 may remain below the high-concentration impurity region 91.

Consequently, the retrograde region 62, the upper channel region 63, the low-concentration impurity region 64, and the high-concentration impurity region 91 may be stacked within the active region 52. Also, the upper channel region 63 may be electrically isolated from the semiconductor substrate 51 by the retrograde region 62.

### EXAMPLES

Table 1 shows the results of changes in threshold voltage due to a body effect in accordance with some embodiments of the present invention.

TABLE 1
Change in threshold voltage due to body effect

| Item | Sample 1 | Sample 2 |
|---|---|---|
| P ion implantation | 0 | 180 KV, 5E+12atoms/cm² |
| Threshold voltage | 0.699 V | 0.683 V |
| BE | 0.287 V/−1 V | 0.162 V/−1 V |

In Table 1, Sample 1 and Sample 2 are fabricated to have a gate length of 35 nm, a gate width of 50 nm, and a gate trench depth of 180 nm. A phosphorus ion implantation process for forming a retrograde region is performed on Sample 2, and is not performed on Sample 1. The phosphorus ion implantation process for forming a retrograde region is performed on Sample 2 at an energy of 180 KV and a dose of 5E+12 atoms/cm²

Referring to Table 1, threshold voltages of Sample 1 and Sample 2 are 0.699V and 0.683V, respectively. That is, it can be found that the threshold voltages of Sample 1 and Sample 2 have similar levels to each other. The threshold voltage change rate BE of Sample 1 due to the body bias is 0.287V/−1V, and the threshold voltage change rate BE of Sample 2 due to the body bias is 0.162V/−1V. That is, it can be found that the threshold voltage change rate BE of Sample 2 due to the body bias is decreased by about 50% compared to Sample 1.

In conclusion, it is possible in some embodiments to effectively control increases in threshold voltage due to a body effect using the retrograde region.

According to some embodiments of the present invention as described above, an active region is defined in a semiconductor substrate having first type impurity ions. The active region may have a retrograde region, an upper channel region, a lower channel region, and a pair of source and drain regions spaced apart from each other. The retrograde region has second type impurity ions. A gate electrode is disposed to fill a gate trench formed in the active region. The gate electrode is disposed between the source and drain regions and penetrates the upper channel region to extend into the retrograde region. Accordingly, when a gate voltage not less than a threshold voltage is applied to the gate electrode, a channel may be formed in the upper channel region and the lower channel region, which correspond to a lower surface of the gate electrode. That is, an effective channel length can be increased using the gate trench.

Also, the upper channel region and the lower channel region can be electrically isolated from the semiconductor substrate by the retrograde region. Therefore, it is possible in some embodiments to effectively control an increase in threshold voltage due to a body bias. Consequently, a semiconductor device can be implemented which limits or even prevents a threshold voltage from being increased due to a body effect while increasing an effective channel length.

The foregoing is illustrative of the present invention and is not to be construed as limiting thereof. Although a few embodiments of this invention have been described, those skilled in the art will readily appreciate that many modifications are possible in the embodiments without materially departing from the novel teachings and advantages of this invention. Accordingly, all such modifications are intended to be included within the scope of this invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The invention is defined by the following claims, with equivalents of the claims to be included therein.

What is claimed is:

1. A semiconductor device, comprising:
an active region defined in a semiconductor substrate having first type impurity ions;
a retrograde region in the active region and having second type impurity ions;
an upper channel region on the retrograde region in the active region and having the first type impurity ions;
source and drain regions on the upper channel region in the active region and spaced apart from each other; and
a gate electrode filling a gate trench formed in the active region, wherein the gate electrode is disposed between the source and drain regions and extends into the retrograde region through the upper channel region.

2. The semiconductor device of claim 1, wherein the first type is a P type and the second type is an N type.

3. The semiconductor device of claim 2, wherein the retrograde region contains phosphorous.

4. The semiconductor device of claim 2, wherein the upper channel region contains boron.

5. The semiconductor device of claim 1, wherein the gate trench comprises:
an upper trench; and
a lower trench connected to a lower portion of the upper trench and having a larger width than the upper trench and having a bottom at a lower level than a top surface of the retrograde region so that the lower trench extends into the retrograde region.

6. The semiconductor device of claim 5, wherein the gate electrode comprises:
an upper gate electrode filling the upper trench; and
a lower gate electrode filling the lower trench and having a substantially spherical shape.

7. The semiconductor device of claim 6, further comprising an insulating spacer between the upper gate electrode and the source and drain regions.

8. The semiconductor device of claim 6, further comprising a lower channel region between the lower gate electrode and the retrograde region and having the first type impurity ions, wherein the upper and lower channel regions define a channel region having the first type impurity ions that extends between and connects the source and drain regions and wherein the source and drain regions have the second type impurity ions.

9. The semiconductor device of claim 1, further comprising an isolation layer defining the active region, wherein the retrograde region has a top surface disposed at a higher level than the bottom of the isolation layer to provide a side wall region where the isolation layer contacts the retrograde region.

10. A dynamic random access memory (DRAM), comprising:
a semiconductor substrate having first type impurity ions;
an active region defined in the semiconductor substrate;
a retrograde region in the active region and having second type impurity ions;
an upper channel region on the retrograde region in the active region and having the first type impurity ions;
source and drain regions on the upper channel region in the active region that are spaced apart from each other;
a gate electrode filling a gate trench in the active region, wherein the gate electrode is disposed between the source and drain regions and extends into the retrograde region through the upper channel region;
a lower channel region in the gate trench interposed between the gate electrode and the retrograde region, the upper and lower channel regions defining a channel region extending between and connecting the source and drain regions, wherein the retrograde region electrically isolates the upper and lower channel regions from the semiconductor substrate to control an increase in threshold voltage due to body bias;
an insulating layer on the upper channel region;
a buried contact plug extending through the insulating layer and contacting the source region or the drain region; and
a storage node on the insulating layer and contacting the buried contact plug.

11. The DRAM of claim 10, wherein the first type is a P type and the second type is an N type.

12. The DRAM of claim 11, further comprising an isolation layer defining the active region, wherein the retrograde region has a top surface disposed at a higher level than the bottom of the isolation layer to provide a side wall region where the isolation layer is in contact with the retrograde region.

13. The DRAM of claim 11, wherein the insulating layer comprises a lower and an upper insulating layer, the storage node being on the upper insulating layer, and wherein the DRAM further comprises:
a bit line on the lower insulating layer; and
a bit plug extending through the lower insulating layer and connecting the bit line with the other of the source and drain regions.

14. The DRAM of claim 10, wherein the gate electrode comprises:
an upper gate electrode between the source and drain regions; and
a lower gate electrode connected to a lower portion of the upper gate electrode and having a larger width than the upper gate electrode, wherein the lower gate electrode extends to a lower level than a top surface of the retrograde region so that the lower gate electrode extends into the region and wherein the lower gate electrode has a spherical shape.

15. The DRAM of claim 14, wherein the lower channel region is interposed between the lower gate electrode and the retrograde region and wherein the upper channel region and the lower channel region have the P type impurity ions.

16. A method of forming a semiconductor device, comprising:
providing a semiconductor substrate having first type impurity ions and an active region;
implanting second type impurity ions into the active region to form a retrograde region;
forming a gate trench in the active region and having a bottom at a lower level than an top surface of the retrograde region to extend the gate trench into the retrograde region; and
forming a gate electrode filling the gate trench and extending into the retrograde region.

17. The method of claim 16, wherein providing a semiconductor substrate is preceded by forming an isolation layer in the semiconductor substrate to define the active region, wherein the isolation layer has a lower end disposed at a lower level than the top surface of the retrograde region to provide a side wall region where the isolation layer is in contact with the retrograde region.

18. The method of claim 16, wherein forming the gate trench comprises:
partially etching the active region to form an upper trench; and
forming a lower trench below the upper trench, wherein the lower trench has a larger width than the upper trench and has a bottom disposed at a lower level than the top surface of the retrograde region.

19. The method of claim 18, wherein forming the lower trench is preceded by forming an insulating spacer on a sidewall of the upper trench.

20. The method of claim 16, further comprising implanting the first type impurity ions between the gate electrode and the retrograde region to form a lower channel region.

21. The method of claim 16, wherein the first type is a P type and the second type is an N type.

22. The method of claim 21, further comprising implanting the first type impurity ions into the active region on the retrograde region to form an upper channel region on the retrograde region.

23. The method of claim 22, further comprising implanting the second type impurity ions into the active region on the upper channel region to form source and drain regions.

24. The method of claim 23, further comprising implanting the first type impurity ions between the gate electrode and the retrograde region to form a lower channel region, the lower channel region and upper channel region defining a channel region having the first type impurity ions extending between and connecting the source and drain regions having the second type impurity ions.
